(19) United States
(12) Patent Application Publication
(10) Pub. No.: US 2014/0172327 A1
(43) Pub. Date: Jun. 19, 2014

(54) UNDERGROUND TRANSFORMER ELECTRICAL FAULT DETECTION USING ACOUSTIC SENSING TECHNOLOGY

(71) Applicant: EATON CORPORATION, Cleveland, OH (US)

(72) Inventors: XIN ZHOU, Franklin Park, PA (US); Mark A. Faulkner, Greenwood, SC (US); Deborah K. Mort, Coraopolis, PA (US); John D. Weeks, Arden, NC (US)

(73) Assignee: Eaton Corporation, Cleveland, OH (US)

(21) Appl. No.: 13/718,487

(22) Filed: Dec. 18, 2012

(51) Int. Cl. G01R 31/02; G06F 17/15

(52) U.S. Cl. CPC G01R 31/027; G06F 17/15
USPC 702/58

(57) ABSTRACT

An electrical fault detection system includes an underground transformer unit having an enclosure and an electrical busbar element extending from the enclosure, and an acoustic sensor apparatus operatively coupled to an external structure of the enclosure or the electrical busbar element. The acoustic sensor apparatus is structured to: (i) detect an acoustic signal within the enclosure, (ii) analyze the detected acoustic signal and determine whether the detected acoustic signal is indicative of an electrical fault within the enclosure using an event time correlation (ETC) algorithm, and (iii) responsive to determining that the detected acoustic signal is indicative of an electrical fault, output a message indicating that a fault has been detected.

### BACKGROUND

### Field

The disclosed concept relates generally to underground transformers, and, in particular, to a system and method for detecting electrical faults in underground transformers using acoustic sensing technology.

### Background Information

Underground transformers are used with underground electric power distribution lines at service drops to step down the primary voltage on the line to the lower secondary voltage supplied to utility customers. In general, there are three different types of underground transformers: (i) pad-mount type transformers wherein the transformer enclosure (which houses the actual transformer) is mounted on a pad at ground level and is operated/accessed while standing next to it, (ii) subsurface type transformers wherein the transformer enclosure (which houses the actual transformer) is installed underground and includes a removable top/door so that it can be operated/accessed while standing at ground level next to the open enclosure, and (iii) vault type transformers wherein the transformer enclosure (which houses the actual transformer) is placed inside an underground concrete vault that is accessed by climbing down into the vault through an overhead manhole (e.g., directly from the street). Often times in such transformers, the transformer enclosure housing the actual transformer is filled with a fluid media for cooling, such as, without limitation, oil (other possibilities include silicone or a very high temp vegetable FR3 compound). It is possible, however, that the transformer enclosure is not filled with a fluid media for cooling.

The deterioration of electrical joints, fluid media quality (if present) and/or insulation materials within an underground transformer will often lead to undesirable electrical faults including overheated electrical joints and/or partial discharge. If these types of electrical faults are not detected and prevented, they could cause major fire hazards and/or transformer explosions. There is currently no cost effective prior art technology or product for providing continuous (e.g., “24-7” or 24 hours a day, seven days a week) monitoring and detection of electrical faults inside underground transformers.

The common practice is to inspect underground transformers during regular maintenance. In addition, it is also known to place temperature sensors and smoke detectors on the transformer enclosures and/or in the vault of vault type transformers for monitoring temperature and detecting smoke and/or fire in the case of a fault induced incident. These technologies, however, are not able to detect overheated electrical joints and/or partial discharge within underground transformers until it is too late.

### SUMMARY

These needs and others are met by embodiments of the disclosed concept, which are directed to a system and method for detecting electrical faults within an underground transformer unit using acoustic sensing technology.

In one embodiment, an electrical fault detection system is provided that includes an underground transformer unit having an enclosure (e.g., without limitation, filled with a fluid media for cooling) and an electrical busbar element extending from the enclosure, and an acoustic sensor apparatus operatively coupled to an external structure of the enclosure or the electrical busbar element. The acoustic sensor apparatus is structured to: (i) detect an acoustic signal within the enclosure , (ii) analyze the detected acoustic signal and determine whether the detected acoustic signal is indicative of an electrical fault within the enclosure using an event time correlation (ETC) algorithm, and (iii) responsive to determining that the detected acoustic signal is indicative of an electrical fault, output a message indicating that a fault has been detected.

In another embodiment, a method of detecting an electrical fault in an underground transformer unit is provided. The method includes detecting a acoustic signal within the underground transformer unit at a position external to the underground transformer unit, analyzing the detected acoustic signal and determining that the detected acoustic signal is indicative of an electrical fault within the underground transformer unit using an event time correlation (ETC) algorithm, and responsive to determining that the detected acoustic signal is indicative of an electrical fault, generating a message indicating that a fault has been detected.

### BRIEF DESCRIPTION OF THE DRAWINGS

A full understanding of the disclosed concept can be gained from the following description of the preferred embodiments when read in conjunction with the accompanying drawings in which:

FIGS. 1 and 2 are schematic diagrams of a fault detection system for detecting faults in an underground transformer high voltage switch enclosure according to an exemplary embodiment of the present invention;

FIG. 3 is a schematic diagram of an acoustic sensor apparatus of the system of FIGS. 1 and 2 according to one exemplary, non-limiting particular embodiment; and

FIGS. 4A-4B are flowcharts illustrating a routine for detecting faults from detected acoustic signals using an event time correlation (ETC) algorithm according to one exemplary embodiment of the present invention that may be implemented in the system of FIGS. 1 and 2.

### DESCRIPTION OF THE PREFERRED EMBODIMENTS

Directional phrases used herein, such as, for example, left, right, front, back, top, bottom and derivatives thereof, relate to the orientation of the elements shown in the drawings and are not limiting upon the claims unless expressly recited therein.

As employed herein, the statement that two or more parts are “coupled” together shall mean that the parts are joined together either directly or joined through one or more intermediate parts.

As employed herein, the term “number” shall mean one or an integer greater than one (i.e., a plurality).

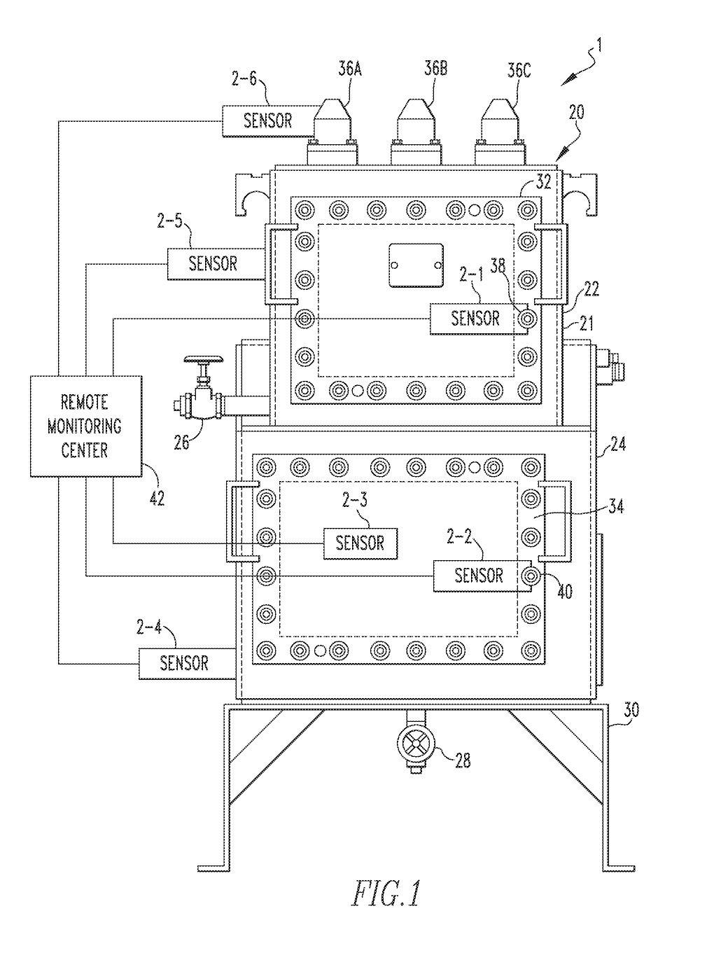

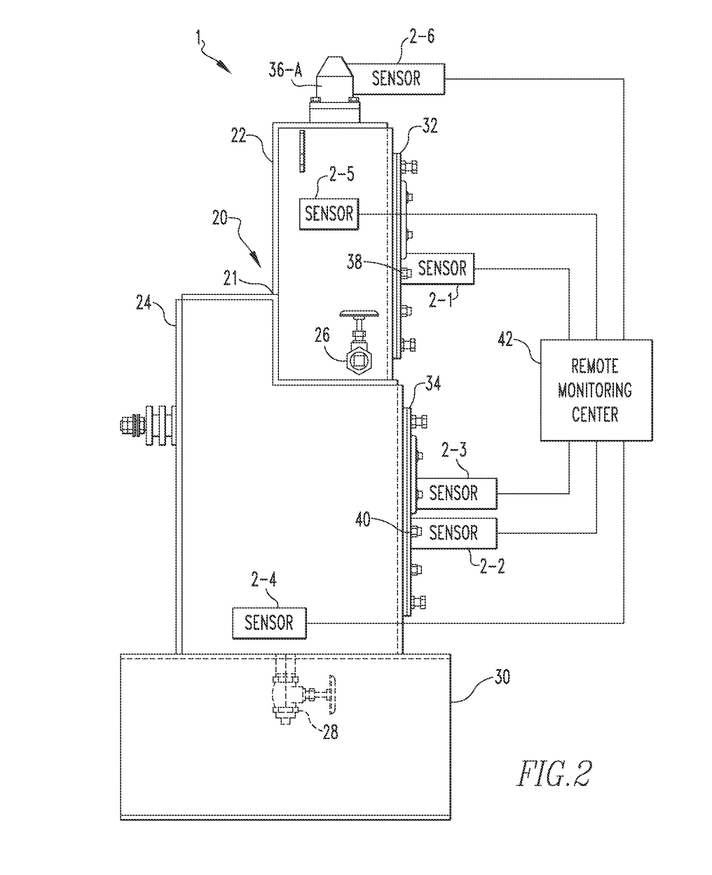

FIGS. 1 and 2 are schematic diagrams (front and side views, respectively) of a fault detection system 1 according to an exemplary embodiment of the present invention. As seen in FIGS. 1 and 2, fault detection system 1 includes an underground transformer high voltage switch enclosure 20 and, as described in greater detail herein, is configured to detect faults including overheated electrical joints and/or partial discharge within underground transformer high voltage switch enclosure 20 using a number of acoustic sensor apparatuses 2 that are coupled to underground transformer high voltage switch enclosure 20. While the specific embodiments of the disclosed concept described herein relate to and include underground transformer high voltage switch enclosure 20, it will be appreciated the concept described herein can also be applied to other types of enclosures forming a part of an underground transformer unit. In addition, in the illustrated embodiment, underground transformer high voltage switch enclosure 20 is part of a vault type transformer, although it will be understood that other types of underground transformers, including pad-mount type transformers and subsurface type transformers, are also contemplated within the scope of the present invention.

Underground transformer high voltage switch enclosure 20 includes an enclosure 21 comprising two chambers, namely a terminal chamber 22 which houses the transformer components (e.g., input terminals) of underground transformer high voltage switch enclosure 20 and a switch chamber 24 which houses the safety switching assembly of underground transformer high voltage switch enclosure 20. Both terminal chamber 22 and switch chamber 24 are, in the exemplary embodiment, filled with a fluid media such as oil and each includes a respective drain valve 26, 28 for fluid draining purposes (it will be understood, however, that it is possible that the enclosure 21 is not filled with a fluid media for cooling). As seen in FIGS. 1 and 2, terminal chamber 22 rests on top of switch chamber 24, and electrical busbar elements 36A, 36B and 36C extend out of terminal chamber 22. Switch chamber 24 is secured to a chamber stand 30. In addition, terminal chamber 22 includes a terminal chamber cover 32, and switch chamber 24 includes a switch chamber cover 34.

As seen in FIGS. 1 and 2, a number of acoustic sensor apparatuses 2, described in detail elsewhere herein, are operatively coupled (e.g., physically attached) to the external structure of enclosure 21 and/or one or more of the electrical busbar elements 36A, 36B and 36C by any of a number of suitable attachment means. In the illustrated, non-limiting exemplary embodiment, fault detection system 1 includes six acoustic sensor apparatuses 2, labeled 2-1 through 2-6 in FIGS. 1 and 2. In particular, as seen in FIGS. 1 and 2, acoustic sensor apparatus 2-1 is bolted or clamped to an existing bolt 38 of terminal chamber cover 32 and acoustic sensor apparatus 2-2 is bolted or clamped to an existing bolt 40 of switch chamber cover 34. Acoustic sensor apparatus 2-3 is attached to the outer surface/wall of switch chamber cover 34 using, for example, a permanent magnet or some other suitable coupling mechanism. Similarly, acoustic sensor apparatus 2-4 is attached to the outer surface/wall of switch chamber 24 using, for example, a permanent magnet or some other suitable coupling mechanism, and acoustic sensor apparatus 2-5 is attached to the outer surface/wall of terminal chamber 22 using, for example, a permanent magnet or some other suitable coupling mechanism. Finally, acoustic sensor apparatus 2-6 is attached to electrical busbar element 36A using, for example, a permanent magnet, clamp or some other suitable coupling mechanism. As will be appreciated, more or less acoustic sensor apparatuses 2 (as compared to what is shown in FIGS. 1 and 2) may be employed within the scope of the present invention.

As described in greater detail herein, each of the acoustic sensors apparatuses 2 is structured to detect an acoustic signal from within underground transformer high voltage switch enclosure 20, and analyze the detected acoustic signal to determine whether the acoustic signal is indicative of a fault including overheated electrical joints and/or partial discharge within underground transformer high voltage switch enclosure 20. As seen in FIGS. 1 and 2, each of the acoustic sensors apparatuses 2 is in wired or wireless electronic communication with a computerized remote monitoring center 42, and the acoustic sensors apparatuses 2 are each structured to output information to remote monitoring center 42 that is indicative of the fault state of underground transformer high voltage switch enclosure 20. In the exemplary embodiment, each acoustic sensor apparatus 2 senses the acoustic signal generated by overheated electrical joints, partial discharge or arcing that propagates through electrical cables, busbars and/or the fluid inside the enclosure 21 of underground transformer high voltage switch enclosure 20. The acoustic sensor apparatus 2 analyzes that acoustic signal using an event time correlation (ETC) algorithm to determine whether the acoustic signal is induced by the above electrical faults instead of other phenomena or activities such as the humming of the transformer windings. As used herein, an “event time correlation (ETC) algorithm” shall refer to a detection method based on acoustic wavelet profile(s) and the correlation between the wavelet frequency and the electrical power frequency. Responsive to the detection of an electrical fault, the acoustic sensor apparatus 2 will send out a message to remote monitoring center 42 (either via wired or RF wireless communication). The message can include, without limitation, one or more of the following pieces of information: (i) fault detected, (ii) sensor ID, (iii) acoustic signal intensity (or peak value), and (iv) the time of the acoustic peak value detected.

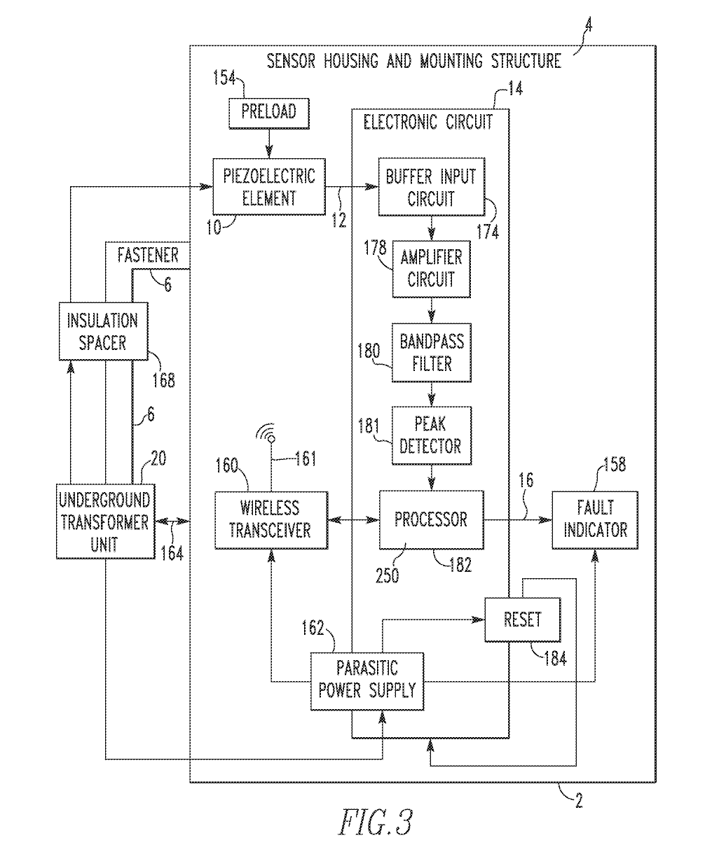

FIG. 3 is a schematic diagram of acoustic sensor apparatus 2 according to one exemplary, non-limiting particular embodiment. Acoustic sensor apparatus 2 shown in FIG. 3 is also described in detail in U.S. Patent Application Publication No. 2012/0095706, which is owned by the assignee hereof and which is incorporated herein by reference in its entirely. Referring to FIG. 3, acoustic sensor apparatus 2 includes a housing, such as an example sensor housing and mounting structure 4, a fastener 6 structured to fasten together at least the housing 4 and the portion of underground transformer high voltage switch enclosure 20 to which acoustic sensor apparatus 2 is operatively coupled, an acoustic sensor, such as the example piezoelectric element 10, structured to detect an acoustic signal from underground transformer high voltage switch enclosure 20 and output a signal 12, and a circuit, such as an example electronic circuit 14, structured to detect an electrical fault 16 from the signal 12.

The example acoustic sensor apparatus 2 includes the example sensor housing and mounting structure 4, the fastener 6, the example piezoelectric element 10, an optional preload 154, the example electronic circuit 14 that outputs the electrical fault signal 16, a fault indicator 158, a communication device, such as a wired transceiver, a wired transmitter, a wireless transmitter, or a wireless transceiver 160 including an antenna 161, and a power supply 162.

The preload 154, which is not required, compresses the piezoelectric element 10 under pressure in its assembly. The “preload” means that the piezoelectric element 10 is compressed or under pressure in its assembly. The preload 154, which is applied to the example piezoelectric element 10, can be, for example and without limitation, a compression element such as a loaded compression spring.

The sensor housing and mounting structure 4 is suitably fastened, at 164, to the portion of underground transformer high voltage switch enclosure 20 to which acoustic sensor apparatus 2 is operatively coupled. The example piezoelectric element 10 is coupled to that portion by a suitable insulation spacer 168 or through the sensor housing by a suitable insulating spacer (not shown). For example, the sensor housing and mounting structure 4 may fastened (e.g., without limitation, bolted) onto the external structure of enclosure 21 and/or one or more of the electrical busbar elements 36A, 36B and 36C as described elsewhere herein.

Although the power supply 162 is shown as being an example parasitic power supply (e.g., without limitation, employing a current transformer (CT) (not shown) that derives power from the busbars or cables connecting to underground transformer high voltage switch enclosure 20, it will be appreciated that a wide range of power supplies, such as external power or batteries, can also be employed.

The wireless transceiver 160 provides a suitable wireless communication capability (e.g., without limitation, IEEE 802.11; IEEE 802.15.4; another suitable wireless transceiver or transmitter) to communicate the detection of an electrical fault to another location (e.g., without limitation, to remote monitoring center 42) to alert maintenance personnel of the electrical fault and its location.

As seen in FIG. 3, the exemplary electronic circuit 14 includes a buffer input circuit 174 that receives the output signal 12 (e.g., an acoustic signal) from the piezoelectric element 10, an amplifier circuit 178, a bandpass filter 180, a peak detector 181 and a processor 182. A reset circuit 184 can reset the electronic circuit 14 after a power outage caused by the parasitic power supply 162 receiving insufficient power.

The piezoelectric element 10 senses acoustic signals propagating through the external structure of enclosure 21 and/or one or more of the electrical busbar elements 36A, 36B and 36C, and outputs the signal 12 to the buffer input circuit 174, which outputs a voltage signal to the amplifier circuit 178. The voltage signal is amplified by the amplifier circuit 178 that outputs a second signal. The second signal can be filtered by the bandpass filter 180 and input by the peak detector 181 that detects a peak signal and outputs that as a third signal. The third signal is analyzed by a routine 250 of the processor 182, in order to detect the electrical fault therefrom. This determines if an electrical fault, such as overheated electrical joints and/or partial discharge, exists within underground transformer high voltage switch enclosure 20. As noted elsewhere herein, routine 250 of the processor 182 analyzes the acoustic signal using the event time correlation (ETC) algorithm to determine whether the acoustic signal is induced by an electrical fault instead of other phenomena or activities such as the humming of the transformer windings.

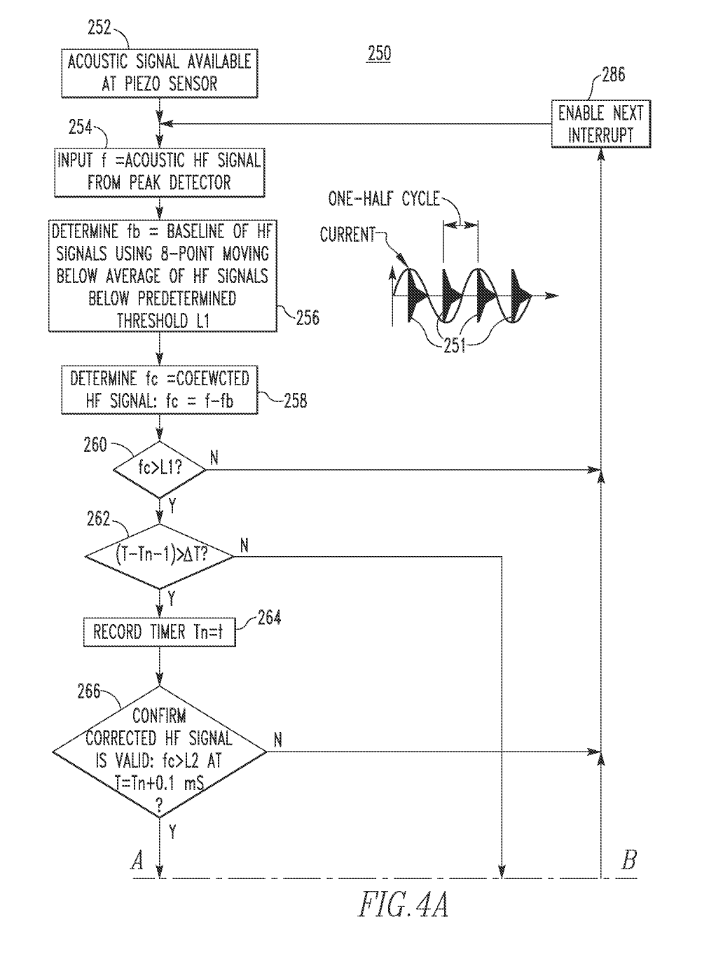

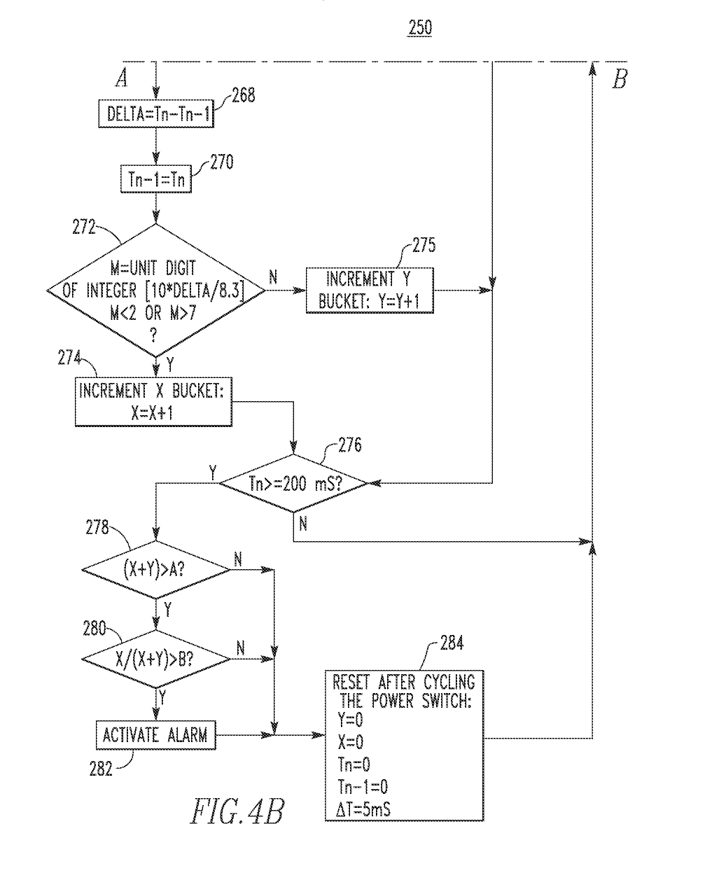

Referring to FIGS. 4A-4B, the routine 250 for processor 182 using the event time correlation (ETC) algorithm according to one exemplary embodiment of the present invention is shown. The general operation of this routine 250 is to obtain output from the peak detector 181 of FIG. 3 and measure DELTA (step 268), the time difference between two adjacent signals from the peak detector 181. The determination of whether an electrical fault exists within underground transformer high voltage switch enclosure 20 is based on this determined/measured DELTA and the acoustic wavelet profile.

First, at 252, an acoustic signal is available at the piezoelectric element 10 and the peak acoustic signal therefrom is available at the peak detector 181. Next, at 254, the routine 250 inputs a signal, f, which is the acoustic high frequency (HF) signal from the peak detector 181.

Then, at 256, a value, fb, is determined, which is the baseline of the HF signals using, for example, an 8-point moving average of the HF signals below a predetermined threshold L1. Two L1 and L2 thresholds are employed by the routine 250 to confirm that acoustic wavelets 251 have the intended profile representative of an electrical fault within underground transformer high voltage switch enclosure 20. Non-limiting examples of L1 and L2 are 100 mV and 50 mV, respectively. Sometimes, the HF signal from the peak detector 181 has a relatively high noise level due to various reasons such as, for example, increased EMI noise. In order to avoid the effect of baseline noise level variation, step 256 seeks to take the noise level out of the measured signal by estimating the noise level using the example 8-point moving average on those HF signals below the predetermined threshold L1. The example 8-point moving average is the average value of the last example eight samples whose values are below the L1 threshold. Next, at 258, the corrected HF signal, fc, is determined from f−fb.

At 260, it is determined if fc is greater than L1. If so, then it is determined if T−Tn−1 is greater than ΔT (e.g., a predefined value such as 5 mS) at 262. T is the time from a suitable timer (not shown) (e.g., without limitation, an oscillator circuit (not shown) in the processor 182 of FIG. 3; a crystal oscillator (not shown) in the processor 182). DELTA is reset to zero at 284 (where Tn=Tn−1=0) after the routine 250 reaches its predetermined time period at 276. If the test passes at 262, then at 264, the timer value, T, is recorded as Tn. Tn=T means that time T is recorded as Tn when there is an acoustic signal coming out of the peak detector 181 that is higher than the L1 threshold. Next, step 266 confirms that the corrected HF signal is valid if fc is greater than L2 at T=Tn+0.1 mS. If so, then variable DELTA is set equal to Tn−Tn−1. Then, at 270, Tn−1 is set equal to Tn.

Next, at 272, it is determined if M is less than 2 or greater than 7, where M is the unit digit of integer [10*DELTA/8.3333]. This checks if DELTA is a multiple of 8.3333 mS (e.g., without limitation, DELTA/8.3333=2.1, then (DELTA/8.3333)×10=21, and M=1 which is less than 2. So DELTA in this case can be considered as a multiple of 8.3333 mS considering the potential measurement error. Effectively, step 272 determines if DELTA is a multiple of one-half line cycle (e.g., without limitation, about 8.3 mS). M represents the digit after the digit point, such as, for example, M=2 for 3.24 or M=8 for 5.82. If the test passes at 272 and DELTA is a multiple of one-half line cycle, then, at 274, one is added to an X bucket. On the other hand, if DELTA is not a multiple of one-half line cycle, then, at 275, one is added to a Y bucket.

After steps 274 or 275, or if the test failed at 262, then at 276, it is determined if Tn is greater than or equal to a predetermined time (e.g., without limitation, 200 mS; 2 S; 10 S; one day). If so, then at 278 and 280, the routine 250 checks two criteria before it declares that the noise is induced by an electrical fault, such as an overheated electrical joint or partial discharge. Step 278 checks if X+Y>=A (e.g., without limitation, 10; 15; any suitable value); and step 280 checks if the ratio of X/(X+Y)>B (e.g., without limitation, 60%; any suitable percentage less than 100%). If these two tests pass, then an alarm (e.g., the fault indicator 158 of FIG. 3) is activated at 282. Otherwise, if one or both of these two tests fail, or after 282, the routine 250 causes a reset after cycling of power (e.g., if power from the power supply 162 of FIG. 3 cycles; if a manual power switch (not shown) is cycled), then values Y, X, Tn and Tn−1 are reset to zero and ΔT is set to 5 mS at 284, and the next interrupt is enabled at 286. Step 286 is also executed if any of the tests fail at 260, 266 and/or 276. Interrupts occur periodically (e.g., without limitation, every 100 .μS). Also, the X and Y buckets of respective steps 274 and 275 are reset to zero after a predetermined time (e.g., without limitation, 10,000 mS; any suitable time).

According to a further aspect of the present invention, multiple acoustic sensor apparatuses 2 can be operatively coupled to underground transformer high voltage switch enclosure 20 (e.g., see FIGS. 1 and 2) and used to determine the location of the fault inside underground transformer high voltage switch enclosure 20 using a known or hereafter developed signal triangulation methodology. In particular, this can be done in remote processing center 42 based on the acoustic signal intensities or magnitudes from multiple acoustic sensor apparatuses 2 attached to the underground transformer high voltage switch enclosure 20 at different locations. These acoustic signal magnitudes, due to the attenuation and the time the acoustic signal takes to reach each sensor, depend on the r (distance) of the electrical fault in a spherical coordinate system. With this set of information, the location of the electrical fault can be estimated or calculated in a known manner, such as the methodology described in Markalous et el., Detection and Location of Partial Discharges in Power Transformers Using Acoustic and Electromagnetic Signals, IEEE Transactions on Dielectrics and Electrical Insulation, Vol 15, No 6, p. 1576-1583, December 2008.

While specific embodiments of the disclosed concept have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosed concept which is to be given the full breadth of the claims appended and any and all equivalents thereof.

What is claimed is:

1. An electrical fault detection system, comprising:
an underground transformer unit having an enclosure and an electrical busbar element extending from the enclosure; and
an acoustic sensor apparatus operatively coupled to an external structure of the enclosure or the electrical busbar element, the acoustic sensor apparatus being structured to: (i) detect an acoustic signal within the enclosure, (ii) analyze the detected acoustic signal and determine whether the detected acoustic signal is indicative of an electrical fault within the enclosure using an event time correlation (ETC) algorithm, and (iii) responsive to determining that the detected acoustic signal is indicative of an electrical fault, output a message indicating that a fault has been detected.

2. The electrical fault detection system according to claim 1, wherein the acoustic sensor apparatus comprises a circuit, wherein the circuit is structured to detect a number of peak signals based on the detected acoustic signal and to determine whether the detected acoustic signal is indicative of an electrical fault within the enclosure based on a time difference between adjacent ones of the peak signals and an acoustic noise wavelet profile of the detected acoustic signal.

3. The electrical fault detection system according to claim 2, wherein the circuit comprises an amplifier structured to generate an amplified signal based on the detected acoustic signal, a band filter structured to filter the amplified signal, a peak detector structured to detect the number of peak signals based on the filtered signal, and a processor structured to determine whether the detected acoustic signal is indicative of an electrical fault within the enclosure based on the time difference between the adjacent ones of the peak signals.

4. The electrical fault detection system according to claim 1, wherein the acoustic sensor apparatus is operatively coupled to the electrical busbar element, and wherein the electrical fault detection system includes a number of additional acoustic sensor apparatuses operatively coupled to the external structure of the enclosure or the electrical busbar element, each of the additional acoustic sensor apparatuses being structured to: (i) detect the acoustic signal within the enclosure, (ii) analyze the detected acoustic signal and determine whether the detected acoustic signal is indicative of an electrical fault within the enclosure using an event time correlation (ETC) algorithm, and (iii) responsive to determining that the detected acoustic signal is indicative of an electrical fault, output an additional message indicating that a fault has been detected.

5. The electrical fault detection system according to claim 1, wherein the enclosure is an underground transformer high voltage switch enclosure and includes a terminal chamber and a switch chamber.

6. The electrical fault detection system according to claim 1, wherein the acoustic sensor apparatus comprises a piezoelectric element structured to generate a signal responsive to the acoustic signal within the enclosure.

7. The electrical fault detection system according to claim 1, further comprising a remote monitoring center in electronic communication with the acoustic sensor apparatus for receiving the message indicating that a fault has been detected.

8. The electrical fault detection system according to claim 7, wherein the electrical fault detection system includes a number of additional acoustic sensor apparatuses operatively coupled to the external structure of the enclosure or the electrical busbar element, each of the additional acoustic sensor apparatuses being structured to: (i) detect the acoustic signal within the enclosure, (ii) analyze the detected acoustic signal and determine whether the detected acoustic signal is indicative of the electrical fault within the enclosure using an event time correlation (ETC) algorithm, and (iii) responsive to determining that the detected acoustic signal is indicative of the electrical fault, transmit an additional message indicating that a fault has been detected to the remote monitoring center, wherein the remote monitoring center is structured to determine a location of the electrical fault inside the enclosure using the message, each additional message and a signal triangulation methodology.

9. The electrical fault detection system according to claim 1, wherein the electrical fault is selected from the group consisting if an overheated electrical joint within the enclosure, a partial discharge within the enclosure, and arcing within the enclosure.

10. A method of detecting an electrical fault in an underground transformer unit, comprising:
detecting an acoustic signal within the underground transformer unit at a position external to the underground transformer unit;
analyzing the detected acoustic signal and determining that the detected acoustic signal is indicative of an electrical fault within the underground transformer unit using an event time correlation (ETC) algorithm; and
responsive to determining that the detected acoustic signal is indicative of an electrical fault, generating a message indicating that a fault has been detected.

11. The method according to claim 10, wherein the underground transformer unit has an enclosure and an electrical busbar element extending from the enclosure, the method including operatively coupling an acoustic sensor apparatus to an external structure of the enclosure or the electrical busbar element, wherein the detecting, analyzing and determining and generating steps are performed using the acoustic sensor apparatus.

12. The method according to claim 10, wherein the analyzing and determining step includes detecting a number of peak signals based on the detected acoustic signal and determining that the detected acoustic signal is indicative of the electrical fault within the underground transformer unit based on a time difference between adjacent ones of the peak signals and an acoustic noise wavelet profile of the detected acoustic signal.

13. The method according to claim 10, further comprising transmitting the message to a remote monitoring center.

14. The method according to claim 10, further comprising:
detecting the acoustic signal within the underground transformer unit at a second position external to the underground transformer unit;
analyzing the detected acoustic signal at the second position and determining that the detected acoustic signal at the second position is indicative of the electrical fault within the underground transformer unit using an event time correlation (ETC) algorithm;
responsive to determining that the detected acoustic signal at the second position is indicative of an electrical fault, generating a second message indicating that a fault has been detected; and
determining the location of the electrical fault inside the underground transformer unit using the message, the second message and a signal triangulation methodology.

15. The method according to claim 10, wherein the electrical fault is selected form the group consisting if an overheated electrical joint within the enclosure, a partial discharge within the enclosure, and arcing within the enclosure.
